(19) United States
(12) Patent Application Publication
(10) Pub. No.: US 2004/0129385 A1
(43) Pub. Date: Jul. 8, 2004

(54) Pre-loaded plasma reactor apparatus and application thereof

(75) Inventors: Richard Wise, New Windsor, NY (US); Mark Charles Hakey, Fairfax, VT (US); Siddhartha Panda, Beacon, NY (US); Bomy A. Chen, Cupertino, CA (US)

Correspondence Address: Sean F. Sullivan, Esq., Cantor Colburn LLP, 55 Griffin Road South, Bloomfield, CT, 06002, US

(73) Assignee: INTERNATIONAL BUSINESS MACHINES CORPORATION, Armonk, NY

(21) Appl. No.: 10/336,148

(22) Filed: Jan. 2, 2003

(51) Int. Cl. H01L 21/306

(52) U.S. Cl. 156/345.35; 156/345.36

(57) ABSTRACT

A pre-loaded plasma-based processing system comprises a pre-reaction plasma processing chamber, a power source disposed in operable communication with the pre-reaction plasma processing chamber, and a wafer plasma processing chamber disposed in fluid communication with the pre-reaction plasma processing chamber. The pre-reaction plasma processing chamber is configured to effect a plasma-based chemical reaction of reactant materials to produce a reactive radical. The wafer plasma processing chamber is configured to react the reactive radical with a species at a surface of a wafer disposed in the wafer plasma processing chamber. Other embodiments include a method of processing a wafer in a plasma environment and preloading of the reactive gas stream to prevent erosion of wafer masking or etch stop layers.

### BACKGROUND

This disclosure relates generally to plasma-based processing, and, more particularly, to a plasma-based processing apparatus having a pre-reaction chamber in which reactants are pre-loaded for application.

Plasma-based processing is employed in the manufacture of semiconductors as a means of generating highly reactive species for pattern formation and deposition without detrimentally affecting the silicon substrate of the semiconductor wafer or components disposed on the wafer. The performance of the process is a compromise between the gas phase reactivity and the surface phase chemistry. High energy electron chemistry in the gas phase comprises the excitation of plasma electrons in an electromagnetic field. The surface phase chemistry comprises particle flux from the plasma to the wafer surface. Although the degree of heating needed in plasma-based processing is several orders of magnitude less than that needed in the absence of a plasma environment, the particle flux to the wafer surface oftentimes results in a substantial degree of wafer heating. Furthermore, subsequent performance of components on the wafer may be degraded due to outdiffusion of dopants disposed on the wafer surface or in the wafer material when the wafer is heated.

The ion current to the wafer surface is determined in part by the plasma power, which is accordingly adjusted to increase or decrease the flow of reactant neutrals or charged species to the wafer surface. During plasma etching of the substrate, one key metric is the selectivity of the etch process to mask and stop layers. The gas phase feedstock materials fed into the plasma chamber are dissociated to form reactive neutrals and ionic species. The gas phase plasma chemistry is a compromise between the optimal conditions for reactant generation and the optimal conditions to avoid detrimental effects to the exposed wafer surface. For example, low operating pressures may be desired in the wafer processing plasma to prevent isotropy and etch stop due to excessive ion collisions or neutral flux. On the other hand, low operating pressures may contribute to the reduction of the degree of gas phase dissociation due to less frequent electron collisions with feedstock materials. Such a reduction may limit the formation of certain reactive species due to the dissociative activation energies of those species relative to other species in the plasma reaction environment.

Low pressure plasma operating chambers dissociate, ionize, and excite gaseous reactant mixtures. Generally, the gas phase reactivity and the surface phase chemistry are coupled. Flux of the gaseous reactant particles to a wafer surface is controlled to etch the layers disposed on the wafer. Ideally, such flux is orthogonal to the surface to be etched. However, in actual practice, ion trajectories are typically distorted as a result of electron shading caused by local charging and solid angle exclusion of sidewalls of mask material selectively disposed over the layers. Because of the selective excitation of the flux particles by the applied radio frequency fields and poor momentum transfer between electrons and more massive ions and neutral particles, velocity distributions of electrons are more isotropic than the velocity distributions of the positively charged ions. Such a disparity in velocity distributions results in the sidewalls of the mask material becoming negatively charged while adjacently-positioned surfaces to be etched become positively charged. The disparity in charge buildup at adjacently-positioned surfaces results in errant flux patterns and the deflection of ion flux to the interfaces of surfaces, which causes undesirable non-uniform etching and possibly the formation of micro-trenches in the patterned layers or punchthough in the etch stop layer.

Current attempts to address these issues include solutions that manipulate the exact parameters of the surface phase chemistry (e.g., plasma power, pressure, and the like) and determine the end product results from process development. The surface phase chemistry is, however, coupled to the gas phase reactivity. Such a coupling of the surface phase chemistry and the gas phase reactivity compromises the on-wafer performance of the plasma process. Attempts to actually de-couple the gas- and surface phase chemistry using multiple power sources or applying multiple radio frequencies have resulted in only partial de-coupling of the chemistries. What is needed is a system that provides for the effective de-coupling of the reactivity of gas phase reactants and wafer surface chemistry.

### SUMMARY

An exemplary embodiment of a pre-loaded plasma reactor apparatus and its application to a plasma-based processing system is disclosed herein. The apparatus comprises a pre-reaction plasma processing chamber, a power source disposed in operable communication with the pre-reaction plasma processing chamber, and a wafer plasma processing chamber disposed in fluid communication with the pre-reaction plasma processing chamber. The pre-reaction plasma processing chamber is configured to effect a plasma-based chemical reaction of reactant materials to produce a reactive radical. The wafer plasma processing chamber is configured to react the reactive radical with a species at a surface of a wafer disposed in the wafer plasma processing chamber. Other embodiments include a method of processing a wafer in a plasma environment.

### BRIEF DESCRIPTION OF THE DRAWINGS

Referring now to the drawings, wherein like elements are numbered alike in the several Figures:

FIG. 1 is a schematic representation of a pre-reaction apparatus for a plasma-based processing system;

FIG. 2 is a cross-sectional view of a gate defined by contacts on a wafer; and

FIG. 3 is a cross-sectional view of a trench structure disposed on a wafer.

### DETAILED DESCRIPTION

A pre-reaction chamber controls the chemistry of a plasma-based processing apparatus independently of the charge effects at a wafer surface by de-coupling the gas phase reactions from the surface phase reactions. The pre-reaction chamber provides operable environments that are generally undesirable to the surface phase chemistry of the wafer (e.g., high temperature, high plasma power, high pressure, etc.) but desirable to the gas phase formation of preferred reactants for the processing of the wafer.

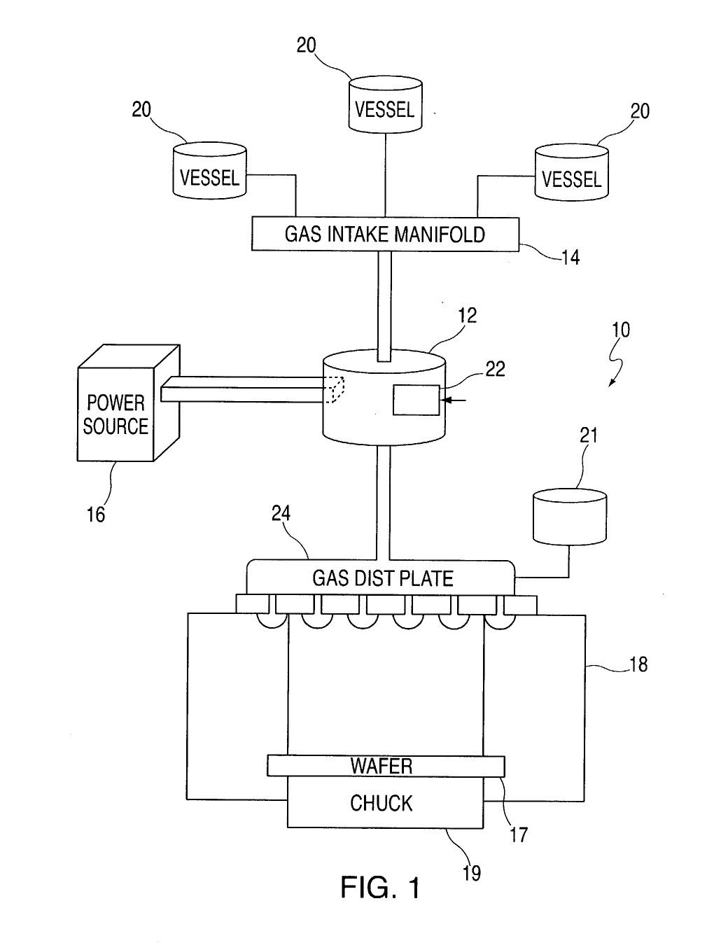

Referring to FIG. 1, one exemplary embodiment of a plasma-based processing apparatus incorporating a pre-reaction plasma processing chamber is shown at 10 and is hereinafter referred to as “apparatus 10.” Apparatus 10 comprises the pre-reaction plasma processing chamber 12 (hereinafter “pre-reaction chamber 12”) disposed in fluid communication with a gas intake manifold 14, a power source 16 disposed in operable communication with 12, and wafer plasma processing chamber 18 disposed in fluid communication with pre-reaction chamber 12. A wafer 17 is disposed at wafer plasma processing chamber 18 via an electrostatically coupled chuck 19. Feedstock gas phase reactants are received into gas intake manifold 14 from reactant sources (e.g., vessels 20) disposed in fluid communication with gas intake manifold 14. A reactive material 22 is disposed within pre-reaction chamber 12. A gas distribution plate 24 is preferably disposed intermediate pre-reaction chamber 12 and wafer plasma processing chamber 18. Preferably, power source 16 is a source of microwave radiation.

The flow of the gas phase reactants from vessels 20 to gas intake manifold 14 generally dictates the operation of pre-reaction chamber 12. Discharge from gas intake manifold 14 is received by pre-reaction chamber 12. Although three vessels 20 are shown as being disposed in fluid communication with gas intake manifold 14 to provide reactant feedstock in accordance with the desired product of the wafer process, any number of vessels may provide any number of reactant feedstocks for apparatus 10.

Pre-reaction chamber 12 is an ex-situ module of apparatus 10 that comprises a pressurizable vessel capable of sustaining a plasma environment in which reactive material 22 is disposed. Reactive material 22 comprises a material capable of preventing the etching of the wafer material when adsorbed by the molecules of the gas phase reactants and subsequently disposed on the wafer surface. Reactive material 22 further comprises the etch stop layer and preferably comprises photoresist, oxide, silicon nitride, or other stop layers, combinations of the foregoing materials, or the like. Maintaining a plasma environment in pre-reaction chamber 12 and contacting the gas phase reactants with a sacrificial film of reactive material 22 provides for the pre-loading of the gas phase reactants.

Subjecting the pre-loaded gas phase reactants to energy derived from power source 16 provides for the generation of a feedstock of reactive radicals for use in the subsequent plasma-based process of wafer plasma processing chamber 18. Generally, the reactive radicals are generated by subjecting the pre-loaded gas phase reactants to high power microwave radiation. The reactive radicals generated are preferably fluorine, carbon, nitrogen, and oxygen radicals, which are generated in accordance with the equations

CHF₃→CHF₂^{•}+F*

O₂→2O*;

CO+CHF₃→COF₂+CHF*; and

N₂→N₂*or N₂⁺

The above listed reactive species (as well as others not listed) are produced at plasma energies that are higher than the plasma energies capable of being withstood by the wafer substrate. The pre-reactive system allows for the formation of such reactive species in an aggressive upstream plasma reactor without the consequent high electron flux to the wafer, electrostatic charging of the wafer, or the detrimental effects associated with high electron flux and electrostatic charging.

Because the gas phase reactants are pre-loaded by their contact with reactive material 22, the actual partial pressures of the reactants in pre-reaction chamber 12 substantially represents the partial pressures that provide saturation of the gases in wafer plasma processing chamber 18 and inhibit production of volatiles from material disposed on the wafer in wafer plasma processing chamber 18. Because wafer plasma processing chamber 18 can then be operated at any regime satisfactory to the wafer processing requirements, operational parameters related to the generation of gas phase radicals are irrelevant. Thus, on-wafer performance is not compromised at the expense of the providing of gas phase reactants to wafer plasma processing chamber 18. For Example, if SiO₂ is being used for a masking material, reactions of the type

SiO₂+2F−>SiOF₂+O

can be employed in the prereactor chamber 12 to form a mixture saturated with SiOF which in turn is fed into wafer plasma processing chamber 18. In the wafer plasma processing chamber, the partial pressure of SiOF may then be adequate to limit the erosion of SiO₂ in the wafer plasma processing chamber 18.

Although apparatus 10 is shown as comprising a single pre-reaction chamber 12 module, it should be understood that apparatus 10 may comprise multiple gas phase reactant chambers that may or may not be pre-reaction chambers. In an apparatus in which multiple gas phase chambers provide the gas phase chemistry, each can be independently controlled to provide increased control of the surface phase chemistry at a wafer surface via an increased level of de-coupling of the gas- and surface phase chemistries. In particular, increasing the amount of control (increased de-coupling) allows for enhanced tuning of the apparatus to allow for the most efficient use of semiconductor materials.

Discharge from pre-reaction chamber 12 comprises a stream of pre-loaded radicals that is received by gas distribution plate 24. Gas distribution plate 24 mixes the pre-loaded radicals and allows for their uniform distribution to wafer plasma processing chamber 18. Because of the pre-loading of the gas phase reactants and the generation of radicals in pre-reaction chamber 12, partial pressures of the product constituents is established prior to the introduction of the gases into wafer plasma processing chamber 18. Control (not shown) provided to gas distribution plate 24 alters the flow of pre-loaded gas phase reactants to wafer plasma processing chamber 18 without providing a penalty resulting from the heating of the wafer, the deposition of excessive plasma material, the excessive charging of the plasma, or a similar problem. Additional reactant feedstocks may be added to gas distribution plate 24 from a source (e.g., a vessel 21) as needed according to the desired product of the particular plasma-based processing of the wafer.

The pre-loaded gas phase reactants are then fed to wafer plasma processing chamber 18, which provides for the dissocation, ionization, and excitation of the molecules of the gas phase reactants. Generation of CF₂ in a low-power reaction for its subsequent implantation into a wafer structure is effected by the equation

C₄F₈→CF₂

Because the gas phase electron chemistry in pre-reaction chamber 12 is independent of the wafer conditions in wafer plasma processing chamber 18, the gas phase reactions are effectively de-coupled from the surface phase reactions (the wafer chemistry). Because the surface phase reactions (on the wafer) are not present in pre-reaction chamber 12, there are no limits on the surface flux or surface chemistry in pre-reaction chamber 12. Therefore, the wafer does not experience excessive charging or thermal flux.

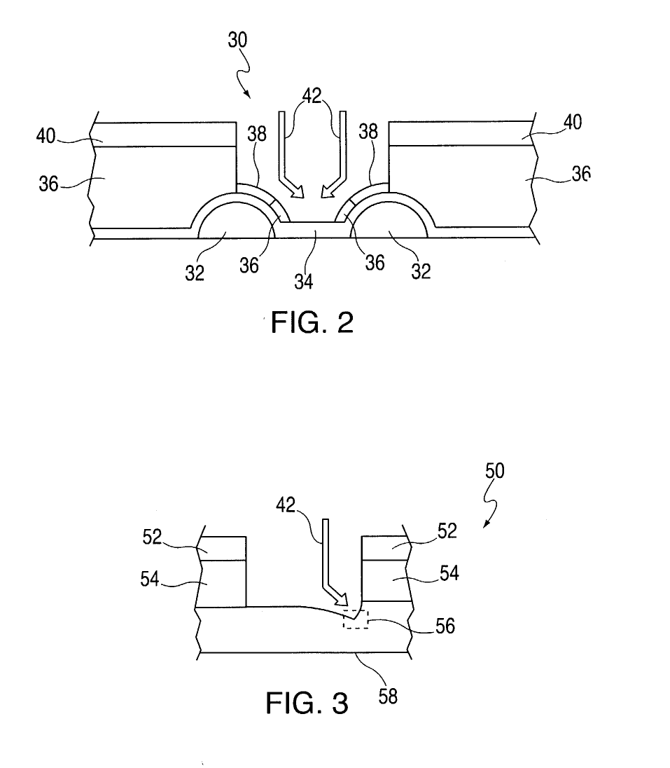

By de-coupling the gas- and surface phase reactions utilizing apparatus 10, radical/ion densities for different feedstock gases can also be independently tuned to mitigate the problem of differential charging. By eliminating or at least minimizing the amount of differential charging of radicals or ions, the anisotropy associated with sheath-directed ion bombardment can be controlled to result in an effective process of utilizing a plasma to etch self-aligned contacts at a wafer surface. Referring now to FIG. 2, one exemplary embodiment of a wafer is shown at 30. Wafer 30 comprises self-aligned contacts 32, a nitride liner 34 disposed over self-aligned contacts 32, an oxide layer 36 disposed over nitride liner 34, a dielectric polymer coating 38 disposed over oxide layer 36 at facing corners of each contact element, and a resistive layer 40 disposed at oxide layer 36. Utilizing the apparatus as described with reference to FIG. 1 to provide for the separation of the gas- and surface phase reactions allows for minimization of the buildup of charge between resistive layer 40 and oxide layer 36, which in turn minimizes the deflection of positively charged ions from the incoming anisotropic ion flux (indicated by arrows 42) to the facing corners of each contact element. By minimizing the bombardment of the corners of each contact element 32, erosion of the corners and tapering of the gates (spaces between contacts 32) is minimized, which in turn preserves the integrity of dielectric polymer coating 38 and minimizes contact resistance and the occurrences of shorting of the componentry disposed at the wafer.

Minimization of differential charging of the wafer layers may further be utilized to reduce the amount of distortion of trench profiles on the wafer surface. One type of trench profile distortion results from the deflection of ion flux in the direction of the corners of an etched feature. Referring now to FIG. 3, a trench structure is shown at 50. A resistive layer 52 is disposed over an oxide layer 54. By de-coupling the gas- and surface phase reactions of the reactants utilizing the apparatus as described above with reference to FIG. 1, the buildup of charge between resistive layer 52 and oxide layer 54 is kept at a minimum. Thus, deflection of ion flux (indicated by arrow 42) to a corner 56 of trench structure 50 is avoided or at least minimized, which in turn allows the structural integrity of a bottom surface 58 (e.g., a nitride layer) of trench structure 50 to be maintained.

As can be seen, the de-coupling of the gas phase reactivity and the surface phase chemistry allows the two phases of the overall plasma-based process to be tuned independently, thereby enabling for the operation of the apparatus in a larger process parameter space. By having the ability to allow for the independent tuning of the apparatus, both low power reactions and high power reactions can be effectively carried out without resulting in a compromise of the power requirements of the apparatus. Further, in systems in which the desired end product requires a more aggressive plasma regime, the gas phase reactants can be accordingly treated in the pre-reaction chamber without detrimentally affecting the sensitive or expensive wafer material in the main plasma processing chamber.

While preferred embodiments have been shown and described, various modifications and substitutions may be made thereto without departing from the spirit and scope of the invention. Accordingly, it is to be understood that the present invention has been described by way of illustration and not limitation.

1. A plasma-based processing apparatus, comprising:
a pre-reaction plasma processing chamber, said pre-reaction plasma processing chamber being configured to effect a plasma-based chemical reaction of a reactant material and an etch stop material;
a power source disposed in operable communication with said pre-reaction plasma processing chamber, said power source being configured to convert the product of said reactant material and said etch stop material into a reactive radical; and
a wafer plasma processing chamber disposed in fluid communication with said pre-reaction plasma processing chamber, said wafer plasma processing chamber being configured to react said reactive radical with a species at a surface of a wafer disposed in said wafer plasma processing chamber.

2. The plasma-based processing apparatus of claim 1, further comprising a gas intake manifold disposed in fluid communication with said pre-reaction plasma processing chamber, said gas intake manifold being disposed in fluid communication with a reactant feedstock source.

3. The plasma-based processing apparatus of claim 1, wherein said etch stop material is a material selected from the group consisting of photoresist, oxides, silicon nitride, and combinations of the foregoing materials.

4. The plasma-based processing apparatus of claim 1, further comprising a gas distribution plate disposed in fluid communication with said pre-reaction plasma processing chamber and said wafer plasma processing chamber, said gas distribution plate being configured to receive said reactive radical from said pre-reaction plasma processing chamber and to discharge said reactive radical to said wafer plasma processing chamber.

5. The plasma-based processing apparatus of claim 4, wherein said gas distribution plate is disposed in fluid communication with a reactant feedstock source.

6. The plasma-based processing apparatus of claim 1, wherein said power source is a microwave radiation source.

7. A method of processing a wafer in a low power plasma environment, said method comprising:
pre-loading a gas phase reactant;
generating a reactive radical from said pre-loaded gas phase reactant; and
reacting said reactive radical with a species in said low power plasma environment.

8. The method of claim 7, wherein said pre-loading of said gas phase reactant comprises,
maintaining said gas phase reactant in a high power plasma environment, and
contacting said gas phase reactant with a reactive material having a photo-resistive capability or an etch stop capability.

9. The method of claim 7, wherein said generating of said reactive-radical comprises subjecting said pre-loaded gas phase reactant to microwave radiation.

10. The method of claim 7, further comprising etching a wafer surface in said low power plasma environment.

11. The method of claim 10, wherein said etching comprises bombarding said wafer surface with a reaction product of said reactive radical and said species in said low power plasma environment.
